(19) United States
(12) Patent Application Publication
(10) Pub. No.: US 2019/0044068 A1
(43) Pub. Date: Feb. 7, 2019

(54) MASK PLATE

(71) Applicant: WUHAN CHINA STAR OPTOELECTRONICS SEMICONDUCTOR DISPLAY TECHNOLOGY CO., LTD., Wuhan, Hubei (CN)

(72) Inventors: Qian JIANG, Shenzhen, Guangdong (CN); YungSheng CHEN, Shenzhen, Guangdong (US)

(73) Assignee: Wuhan China Star Optoelectronics Semiconductor Dis play Technology Co., Ltd., Wuhan, Hubei (CN)

(21) Appl. No.: 15/736,329

(22) PCT Filed: Sep. 21, 2017
(86) PCT No.: PCT/CN2017/102584

§ 371 Date: Dec. 14, 2017

(30) Foreign Application Priority Data
Aug. 1, 2017 (CN) 201710649786.3

(51) Int. Cl. H01L 51/00; H01L 51/56; C23C 14/04

(52) U.S. Cl. CPC H01L 51/0011; C23C 14/042; H01L 51/001; H01L 51/56

(57) ABSTRACT

The present invention provides a mask plate, which comprises an alignment region for obtaining a default reflectance under a certain intensity illumination for alignment; subjecting a reflection process to the alignment region so that the mask plate has a reflectance in the same range as the default reflectance. By the reflection process, it is not necessary to adjust the light intensity or screen contrast to also obtain the same and suitable screen clarity corresponding mask plate when different types of mask plates are in alignment, so as to reduce the manual work for adjustment and increase the production efficiency.

### FIELD OF THE INVENTION

The present invention relates to a technology of Organic electroluminescence display, and more particularly, to a mask plate.

### DESCRIPTION OF PRIOR ART

Organic light-emitting diode (OLED) display with independent light, thin, light weight, fast response, wide viewing angle, rich colors and high brightness, low power consumption, high, low temperature and other advantages, is widely used in mobile phones, watches, computers, machines and other products. Manufacturing OLED generally use vacuum-plating technology, i.e., in a vacuum environment, heating organic/metal materials, and sublimating the materials, forming an organic/metal film having a certain shape by a mask plate having a special pattern, through the continuous deposition of a variety of materials into the film, a multi-layer OLED structure can be formed to form an OLED display finally. In this process, it is necessary to align the mask plate and the substrate to ensure that the pattern to meet the process accuracy requirements. Generally, it uses light to irradiate the alignment region on the mask plate, and then obtaining the resolution of the alignment marks on the alignment region by the alignment system of the vapor deposition machine, to align the mask plate. In the alignment process, the reflectance of the mask plate to the light, determines the screen clarity of the alignment marks, which further determines the accuracy of the alignment marks.

In the production of OLED display process, OLED displays with different resolutions need to use different types of mask plate, producing OLED displays with different resolutions in the same production line, it is necessary to switch the corresponding mask plate according to the resolution of the OLED display, it is further necessary to align the switched mask plate.

In the prior art, in the same production line, and in the process of alignment after switching the different types of mask plates, because the different types of mask plates are different materials and its reflectance to light are also different, in order to ensure accurate alignment, it need to adjust the light intensity or screen contrast according to different reflectance by manpower, a suitable screen clarity of alignment mark corresponding to each type of mask plate, so as to increase the manual work for adjustment and reduce the production efficiency.

### SUMMARY OF THE INVENTION

The present invention mainly provides a mask plate, it is necessary to adjust the light intensity or screen contrast in the same production line after switching different types of mask plates, so as to increase the manual work for adjustment and reduce the production efficiency.

In order to solve the above-mentioned technical problem, a technical solution adopted by the present invention is to provide a mask plate, wherein the mask plate comprises an alignment region for obtaining a default reflectance under a certain intensity illumination for alignment; subjecting a reflection process to the alignment region so that the mask plate has a reflectance in the same range as the default reflectance; wherein the default reflectance is a reflectance of a specific material under the certain intensity illumination; and wherein the mask plate is a metal mask.

In order to solve the above-mentioned technical problem, another technical solution adopted by the present invention is to r provide a mask plate, wherein the mask plate comprises an alignment region for obtaining a default reflectance under a certain intensity illumination for alignment; subjecting a reflection process to the alignment region so that the mask plate has a reflectance in the same range as the default reflectance

The present invention can be concluded with the following advantages, the method provided by the present invention is different from the prior art by subjecting a reflection process to the alignment region of the mask plate so that the mask plate has a reflectance in the same range as the default reflectance. Thus, it is not necessary to adjust the light intensity or screen contrast to also obtain the same and suitable screen clarity corresponding mask plate when different types of mask plates are in alignment, so as to reduce the manual work for adjustment and increase the production efficiency.

### BRIEF DESCRIPTION OF DRAWINGS

FIG. 1 is a structural illustration of a mask plate in accordance with an embodiment in the present invention;

FIG. 2 is an illustrational view of a mask plat in alignment in FIG. 1;

FIG. 3 is a cross sectional view of the first type of mask plate after a reflection process in FIG. 1;

FIG. 4 is a cross sectional view of the first type of mask plate after a reflection process in FIG. 1; and

FIG. 5 is a cross sectional view of the first type of mask plate after a reflection process in FIG. 1.

### DESCRIPTION OF PREFERRED EMBODIMENT

Technical implementation will be described below clearly and fully by combining with drawings made in accordance with an embodiment in the present invention.

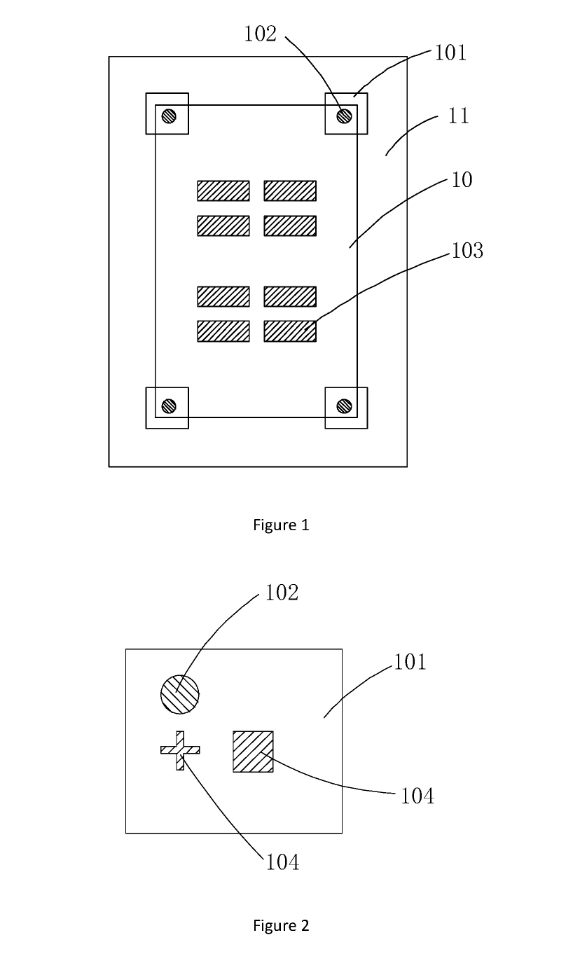

Referring to FIG. 1, the mask plate of the embodiment provided by the present invention comprises an alignment region 101.

Specifically, the mask plate comprises a mask plate body 10, take the mask plate as an example, the mask plate body 10 is a metal sheet and is fixed on a metal frame 11, four alignment regions 101 are arranged on the mask plate body 10, and an alignment mark 102 is arranged on each alignment region 101. Further, a pattern opening region 103 is further arranged on the mask plate body 10.

Optionally, the alignment mark 102 is a circular through hole.

Referring to FIG. 2, when aligning the mask plate with optics, by irradiating a light emitted from a light source to the alignment region 101, obtaining the alignment mark 102 on the alignment region 101 an alignment mark 104 on the substrate by an alignment system, and obtaining these alignment marks to align the mask plate by the alignment system in a suitable screen clarity.

Wherein the alignment region 101 of the present embodiment is used for obtaining a default reflectance under a certain intensity illumination for alignment.

Specifically, subjecting a reflection process to the alignment region 101, so that the mask plate has a reflectance in the same range as the default reflectance

Wherein the default reflectance is a reflectance of a specific material under the certain intensity illumination, i.e., in the present embodiment, the reflectance range obtained by the alignment region 101 of the mask plate under the light is the same as the reflectance range of the specific material.

Optionally, the specific material is an iron-nickel alloy.

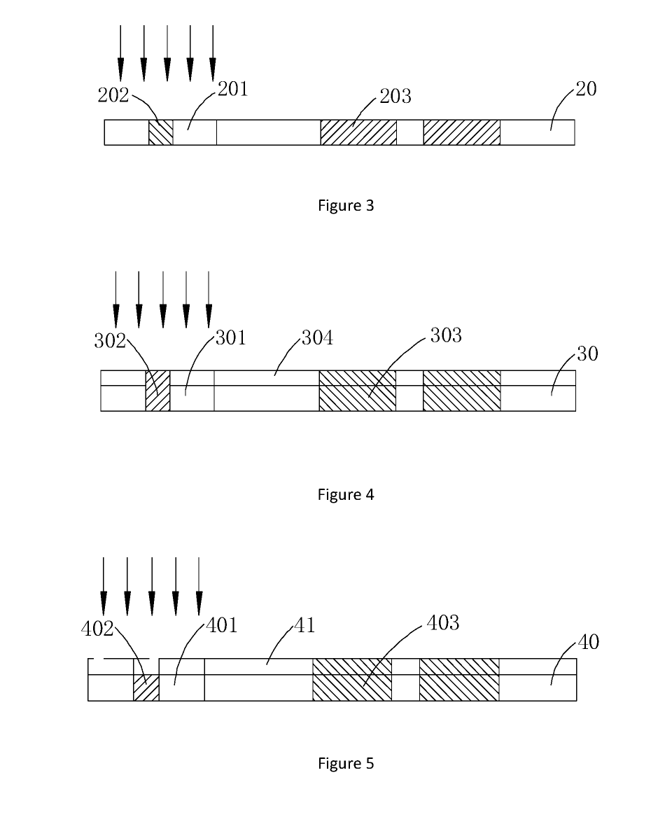

Referring FIGS. 3 to 5, the reflection process to the alignment region of different types of mask plates is different. The present embodiment will be described by taking three types of mask plates as an example.

As shown in FIG. 3, the first type of mask plate is a single-layer structure metal mask plate, which comprises a first pattern layer 20, an alignment region 201 is arranged on the first pattern layer 20, and an alignment mark 202 is arranged on the alignment region 201, further, a plurality of pattern opening region 203 is further arranged on the first pattern layer 20; wherein the specific reflection process to the alignment region 201 of the first pattern layer is: forming the first pattern layer 20 by using a specific material, so that the reflectance obtained by the alignment region 201 is a reflectance of a specific material under the light as shown in figure. It is ensured that the mask plate obtains a reflectance in the same range as a reflectance of a specific material under the light.

Optionally, the first type of mask plate may be made of a high precision metal mask plate of etching method in low-resolution OLED display. The high precision metal mask plate of etching method is based on a metal sheet, after etching by a chemical agent, a pattern is formed on the surface of the metal sheet to form a mask plate. In general, the material of the metal sheet is an iron-nickel alloy, i.e., the first pattern layer 20 is an iron-nickel alloy layer. The reflectance obtained by the alignment region 201 under the light is the reflectance of the iron-nickel alloy, i.e., the reflectance of the specific material.

As shown in FIG. 4, the second type of mask plate is a metal mask plate of multi-layer structure, which comprises a second pattern layer 30, an alignment region 301 is arranged on the second pattern layer 30, and an alignment mark 302 is arranged on the alignment region 301, further, a plurality of pattern opening region 303 is further arranged on the first pattern layer 30; wherein the specific reflection process to the alignment region 301 of the second pattern layer is: forming a first material layer 304 covering the alignment region 301 on the second pattern layer 30, so that the alignment region 301 obtains a reflectance in the same range as the default reflectance under the light.

Specifically, the method may include two methods, the first method is: forming the first material layer 304 covering the alignment region 301 on the second pattern layer 30 by using a specific material, i.e., the first material layer 304 is the specific material layer, so that the reflectance obtained by the alignment region 301 is a reflectance of a specific material under the light as shown in figure, wherein the first material layer 304 may be covered only by a position corresponding to the alignment region 301, or may be a material layer that covers the alignment region 301 and corresponds to the second pattern layer 30; and the second method is: when the reflectance of the second pattern layer 30 is greater than the reflectance of the specific material, forming the first material layer 304 covering the alignment region 301 on the second pattern layer 30 by using a silicon nitride material, i.e., the first material layer 304 is a silicon nitride layer, so that the alignment region 301 obtains a mixed reflectance of the second pattern layer 30 and the silicon nitride layer under the light. Wherein, in the present embodiment, the silicon nitride has a translucent property, and the reflectance of the second pattern layer 30 can be reduced under a light. The degree of reduction of the reflectance of the second pattern layer 30 can be determined by controlling the thickness of the silicon nitride layer, according to the actual situation, so that the reduced reflectance is the same as the range of the default reflectance. Therefore, the mixed reflectance obtained by the alignment region 301 is the same as the range of the default reflectance.

Optionally, the second type of mask plate may be made of a high precision metal mask plate of electroforming method in high-resolution OLED display. The high precision metal mask plate of electroforming method is based on a metal sheet, after photoresist coating, exposure, development, and being energized in a chemical tank, a pattern is formed on the surface of the metal sheet to form a mask plate. In general, the material of the metal sheet is a nickel-cobalt alloy, i.e., the second pattern layer 30 is a nickel-cobalt alloy layer. Using iron-nickel alloy for the specific material, an iron-nickel alloy layer covering the alignment region 301 may be formed on the nickel-cobalt alloy layer, and the composition ratio of the formed iron-nickel alloy layer is the same as the iron-nickel alloy of the specific material, the reflectance obtained in the light field is the reflectance of the iron-nickel alloy, the alignment region obtains a reflectance in the same range as a reflectance of iron-nickel alloy under the light; because reflectance of the nickel-cobalt alloy is larger than the iron-nickel alloy, a silicon nitride layer may further be formed on the above-mentioned iron-nickel alloy layer to reduce the reflectance of the nickel-cobalt alloy layer, so that the reflectance obtained by the alignment region 301 is the same as the range of the default reflectance.

Optionally, the thickness of the silicon nitride layer is 10 angstroms to 9,000 nm.

As shown in FIG. 5, the third type of the mask plate comprises a third pattern layer 40 and a second material layer 41 stacked sequentially, an alignment region 401 is arranged on the second material layer 41, and an alignment mark 402 is arranged on the alignment region 401, a pattern opening region 403 is further arranged on the alignment region 401; wherein the specific reflection process to the alignment region 401 of the third pattern layer is: forming the third pattern layer 40 by using a specific material, and removing the second material layer 41 at a position corresponding to the alignment region 401 to expose the third pattern layer 40, i.e., remove the dotted line part as shown in FIG. 5, so that the reflectance obtained by the alignment region 401 is the reflectance of the third pattern layer 40 under the light, i.e., the reflectance of the specific material.

Optionally, the third type of mask plate may be made of a hybrid medium precision metal mask plate in high-resolution OLED display. Manufacturing the hybrid medium precision metal mask is by forming a polymer film on a metal sheet, then forming a pattern by opening holes by chemical or laser to form a mask plate. In the present invention, using iron-nickel alloy for the specific material, the hybrid medium precision metal mask may be made of iron-nickel alloy, i.e., the third pattern layer 40 is an iron-nickel alloy layer, the polymer film is the second material layer 41. After removing the polymer film at a position corresponding to the alignment region 401, the reflectance obtained by the alignment region 401 is the reflectance of the iron-nickel alloy under the light, i.e., the reflectance of the specific material.

In the specific application, producing OLED displays with different resolutions in the same production line, it is necessary to use different types of mask plates. Take the above-mentioned three types of a high precision metal mask plate of etching method, a high precision metal mask plate of electroforming method, and a hybrid medium precision metal mask plate for example, the first pattern layer of the high precision metal mask plate of etching method may be a specific material layer, i.e., an iron-nickel alloy layer. In the alignment, adjusting the intensity of the light source according to the reflectance of the iron-nickel alloy to obtain a suitable screen clarity. Further, subjecting a reflection process to the high precision metal mask plate of electroforming method and the hybrid medium precision metal mask plate by the above-mentioned processes, when it is necessary to switch the high precision metal mask plate of electroforming method or the hybrid medium precision metal mask plate, the same screen clarity as the high precision metal mask plate of etching method can be obtained, so as to obtain the screen clarity of alignment region of the high precision metal mask plate of electroforming method and the hybrid medium precision metal mask plate.

The method provided by the present invention is different from the prior art by subjecting a reflection process to the alignment region of the mask plate so that the mask plate has a reflectance in the same range as the default reflectance. Thus, it is not necessary to adjust the light intensity or screen contrast to also obtain the same and suitable screen clarity corresponding mask plate when different types of mask plates are in alignment, so as to reduce the manual work for adjustment and increase the production efficiency.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

1. A mask plate, wherein the mask plate comprises an alignment region for obtaining a default reflectance under a certain intensity illumination for alignment;
subjecting a reflection process to the alignment region so that the mask plate has a reflectance in the same range as the default reflectance;
wherein the default reflectance is a reflectance of a specific material under the certain intensity illumination;
and wherein the mask plate is a metal mask.

2. The mask plate as recited in claim 1, wherein the specific material is an iron-nickel alloy.

3. The mask plate as recited in claim 1, wherein the mask plate is a single-layer structure metal mask plate, the mask plate comprises a first pattern layer, and the alignment region is arranged in the first pattern layer; the above-mentioned description of subjecting a reflection process to the alignment region so that the mask plate has a reflectance in the same range as the default reflectance, which comprising:
forming the first pattern layer by using a specific material, so that the alignment region obtains a reflectance of a specific material under the light.

4. The mask plate as recited in claim 1, wherein the mask plate is a metal mask plate of multi-layer structure, the mask plate comprises a second pattern layer, and the alignment region is arranged in the first pattern layer; the above-mentioned description of subjecting a reflection process to the alignment region so that the mask plate has a reflectance in the same range as the default reflectance, which comprising:
forming a first material layer covering the alignment region on the second pattern layer, so that the alignment region obtains a reflectance in the same range as the default reflectance under the light.

5. The mask plate as recited in claim 4, wherein the above-mentioned description of forming a first material layer covering the alignment region on the second pattern layer so that the alignment region obtains a reflectance in the same range as the default reflectance under the light, which comprises:
forming the first material layer covering the alignment region on the second pattern layer by using a specific material, so that the alignment region obtains a reflectance of a specific material under the light.

6. The mask plate as recited in claim 4, wherein the reflectance of the second pattern layer is greater than the reflectance of the specific material; the above-mentioned description of forming a first material layer covering the alignment region on the second pattern layer so that the alignment region obtains a reflectance in the same range as the default reflectance under the light, which comprises:
forming the first material layer covering the alignment region on the second pattern layer by using a silicon nitride material, so that the alignment region obtains a mixed reflectance of the second pattern layer and the silicon nitride layer under the light.

7. The mask plate as recited in claim 6, wherein the second pattern layer is a nickel-cobalt alloy layer.

8. The mask plate as recited in claim 1, wherein the mask plate comprises a third pattern layer and a second material layer stacked sequentially, and the alignment region is arranged in the second material layer; the above-mentioned description of subjecting a reflection process to the alignment region so that the mask plate has a reflectance in the same range as the default reflectance, which comprising:
forming the third pattern layer by using a specific material, and removing the second material layer at a corresponding position of the alignment region to expose the third pattern layer, so that the alignment region obtains a reflectance of a specific material under the light.

9. The mask plate as recited in claim 8, wherein the second material layer is a polymer film layer.

10. A mask plate, wherein the mask plate comprises an alignment region for obtaining a default reflectance under a certain intensity illumination for alignment;
subjecting a reflection process to the alignment region so that the mask plate has a reflectance in the same range as the default reflectance.

11. The mask plate as recited in claim 10, wherein the default reflectance is a reflectance of a specific material under the certain intensity illumination.

12. The mask plate as recited in claim 11, wherein the specific material is an iron-nickel alloy.

13. The mask plate as recited in claim 11, wherein the mask plate is a single-layer structure metal mask plate, the mask plate comprises a first pattern layer, and the alignment region is arranged in the first pattern layer; the above-mentioned description of subjecting a reflection process to the alignment region so that the mask plate has a reflectance in the same range as the default reflectance, which comprising:
forming the first pattern layer by using a specific material, so that the alignment region obtains a reflectance of a specific material under the light.

14. The mask plate as recited in claim 11, wherein the mask plate is a metal mask plate of multi-layer structure, the mask plate comprises a second pattern layer, and the alignment region is arranged in the first pattern layer; the above-mentioned description of subjecting a reflection process to the alignment region so that the mask plate has a reflectance in the same range as the default reflectance, which comprising:
forming a first material layer covering the alignment region on the second pattern layer, so that the alignment region obtains a reflectance in the same range as the default reflectance under the light.

15. The mask plate as recited in claim 14, wherein the above-mentioned description of forming a first material layer covering the alignment region on the second pattern layer so that the alignment region obtains a reflectance in the same range as the default reflectance under the light, which comprises:
forming the first material layer covering the alignment region on the second pattern layer by using a specific material, so that the alignment region obtains a reflectance of a specific material under the light.

16. The mask plate as recited in claim 14, wherein the reflectance of the second pattern layer is greater than the reflectance of the specific material; the above-mentioned description of forming a first material layer covering the alignment region on the second pattern layer so that the alignment region obtains a reflectance in the same range as the default reflectance under the light, which comprises:
forming the first material layer covering the alignment region on the second pattern layer by using a silicon nitride material, so that the alignment region obtains a mixed reflectance of the second pattern layer and the silicon nitride layer under the light.

17. The mask plate as recited in claim 16, wherein the second pattern layer is a nickel-cobalt alloy layer.

18. The mask plate as recited in claim 11, wherein the mask plate comprises a third pattern layer and a second material layer stacked sequentially, and the alignment region is arranged in the second material layer; the above-mentioned description of subjecting a reflection process to the alignment region so that the mask plate has a reflectance in the same range as the default reflectance, which comprising:
forming the third pattern layer by using a specific material, and removing the second material layer at a corresponding position of the alignment region to expose the third pattern layer, so that the alignment region obtains a reflectance of a specific material under the light.

19. The mask plate as recited in claim 18, wherein the second material layer is a polymer film layer.
